(19) United States
(12) Patent Application Publication
(10) Pub. No.: US 2018/0157891 A1
(43) Pub. Date: Jun. 7, 2018

(54) FINGERPRINT FLASH DRIVE

(71) Applicant: Power Quotient International Co., Ltd., New Taipei City (TW)

(72) Inventors: Hung Chi Wang, New Taipei City (TW); Ya Fen Chen, New Taipei City (TW)

(21) Appl. No.: 15/433,639

(22) Filed: Feb. 15, 2017

(30) Foreign Application Priority Data
Dec. 1, 2016 (TW) 105218405

(51) Int. Cl. G06K 9/00; H05K 5/00; H05K 5/03; H05K 1/18; H05K 9/00; H01R 24/64; H01R 13/66

(52) U.S. Cl. CPC G06K 9/00053; G06K 9/00087; H05K 5/0026; H05K 5/03; H05K 1/181; H01R 2107/00; H01R 24/64; H01R 13/6683; H05K 2201/10113; H05K 2201/10151; H05K 9/0007

(57) ABSTRACT

A fingerprint flash drive includes a circuit board, an enclosure and a fingerprint recognizer. The enclosure encloses the circuit board. An insertion direction of the fingerprint flash drive is defined as a front-to-rear direction. The enclosure has a top surface extending along the insertion direction of the fingerprint flash drive, and a front surface connected with a front edge of the top surface. The front surface and the top surface of the enclosure are noncoplanar. A rear end of the enclosure cooperates with the circuit board to form a plug. The fingerprint recognizer is electrically connected with the circuit board and fastened to the front surface of the enclosure. A front surface of the fingerprint recognizer is exposed outside.

### BACKGROUND OF THE INVENTION

1. Field of the Invention

The present invention generally relates to a flash drive, and more particularly to a fingerprint flash drive capable of identifying fingerprints.

2. The Related Art

A current fingerprint flash drive includes a circuit board, an enclosure enclosing the circuit board, and a fingerprint recognizer. The fingerprint recognizer has a top surface extending along a front-to-rear direction. The fingerprint recognizer is adhered to the top surface of the enclosure and is connected with the circuit board. The enclosure includes a plurality of elements which are fastened together. However, the fingerprint recognizer is adhered to the top surface of the enclosure to occupy a larger area of the top surface of the enclosure of the current fingerprint flash drive, so a size of the current fingerprint flash drive is usually larger and is hard to decrease. Moreover, the elements of the enclosure are usually fastened together by virtue of adhesives that will easily stain the fingerprint recognizer to damage the fingerprint recognizer, in that case, quality of the current fingerprint flash drive is worse, and the process of fastening the elements of the enclosure is inconvenient to increase a cost and working hours of fastening the elements of the enclosure of the current fingerprint flash drive.

### SUMMARY OF THE INVENTION

An object of the present invention is to provide a fingerprint flash drive. The fingerprint flash drive includes a circuit board, an enclosure and a fingerprint recognizer. The enclosure encloses the circuit board. An insertion direction of the fingerprint flash drive is defined as a front-to-rear direction. The enclosure has a top surface extending along the insertion direction of the fingerprint flash drive, and a front surface connected with a front edge of the top surface. The front surface and the top surface of the enclosure are noncoplanar. A rear end of the enclosure cooperates with the circuit board to form a plug. The fingerprint recognizer is electrically connected with the circuit board and fastened to the front surface of the enclosure. A front surface of the fingerprint recognizer is exposed outside.

As described above, the fingerprint recognizer is fastened to the front surface of the enclosure to properly utilize an area of the front surface of the enclosure and be without occupying an area of the top surface of the enclosure of the fingerprint flash drive, so a size of the fingerprint flash drive is relatively smaller and is easy to decrease, and the front surface of the fingerprint recognizer is exposed outside for being touched conveniently by a user. Moreover, a fixing holder, a shielding shell, a fastening holder and a front cover are fastened together by virtue of buckling portions being buckled in respective buckling holes, and the process of fastening the fixing holder, the shielding shell, the fastening holder and the front cover is without using adhesives for preventing staining the fingerprint recognizer, in that case, quality of the fingerprint flash drive is better, and the process of fastening the fixing holder, the shielding shell, the fastening holder and the front cover is convenient to decrease a cost and working hours of fastening the fixing holder, the shielding shell, the fastening holder and the front cover of the enclosure of the fingerprint flash drive.

### BRIEF DESCRIPTION OF THE DRAWINGS

The present invention will be apparent to those skilled in the art by reading the following description, with reference to the attached drawings, in which:

FIG. 1 is a perspective view of a fingerprint flash drive in accordance with the present invention;

FIG. 2 is an exploded perspective view of the fingerprint flash drive of FIG. 1;

FIG. 3 is another exploded perspective view of the fingerprint flash drive of FIG. 1;

FIG. 4 is a partially perspective view of the fingerprint flash drive of FIG. 1, wherein a fastening holder and a protecting shell are omitted;

FIG. 5 is a partially perspective view of the fingerprint flash drive of FIG. 1, wherein the protecting shell is omitted;

FIG. 6 is a partially perspective view of the fingerprint flash drive of FIG. 1, wherein the protecting shell and a shielding shell are omitted; and

FIG. 7 is a partially perspective view of the fingerprint flash drive of FIG. 1, wherein a front cover is omitted.

### DETAILED DESCRIPTION OF THE PREFERRED EMBODIMENT

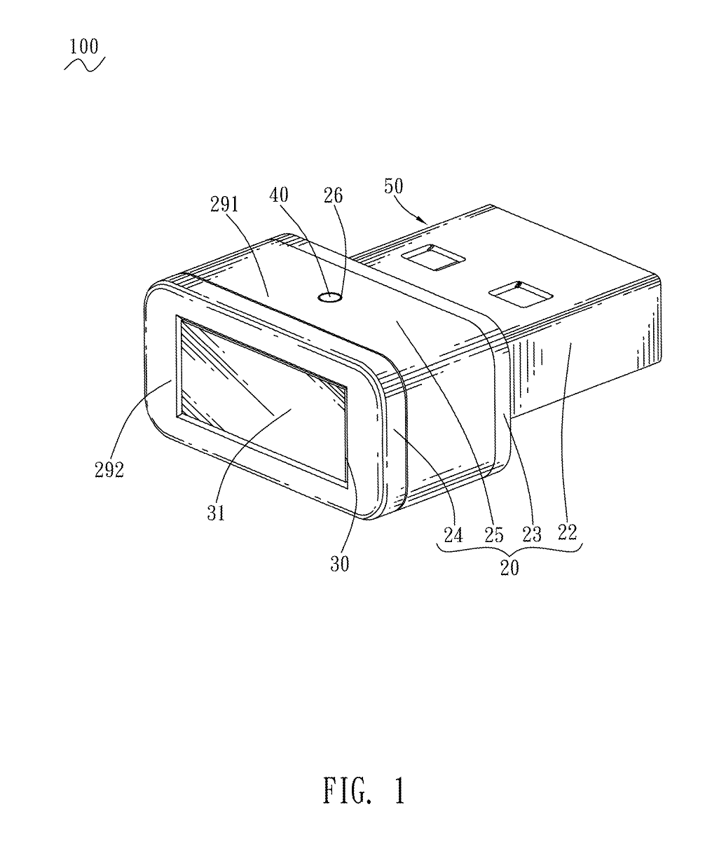

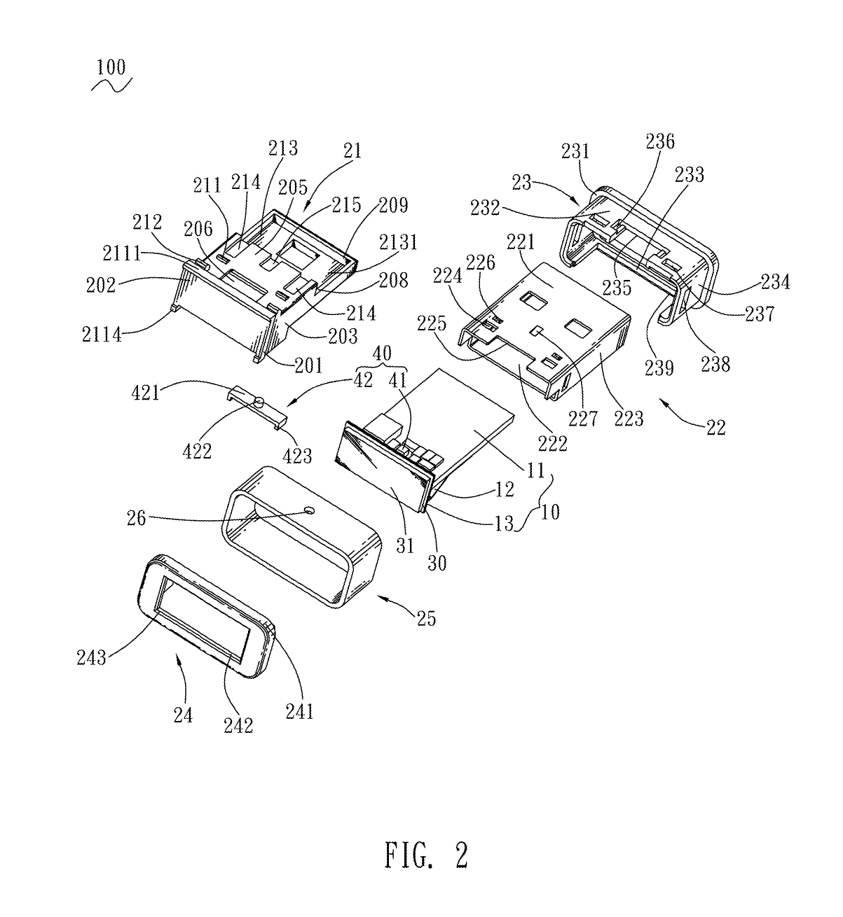

With reference to FIG. 1 and FIG. 2, a fingerprint flash drive 100 in accordance with the present invention is shown. The fingerprint flash drive 100 includes a circuit board 10, an enclosure 20, a fingerprint recognizer 30 and an indicator light 40.

Referring to FIG. 2, the circuit board 10 includes a rigid circuit board 11, a flexible circuit board 12 and a reinforcing board 13.

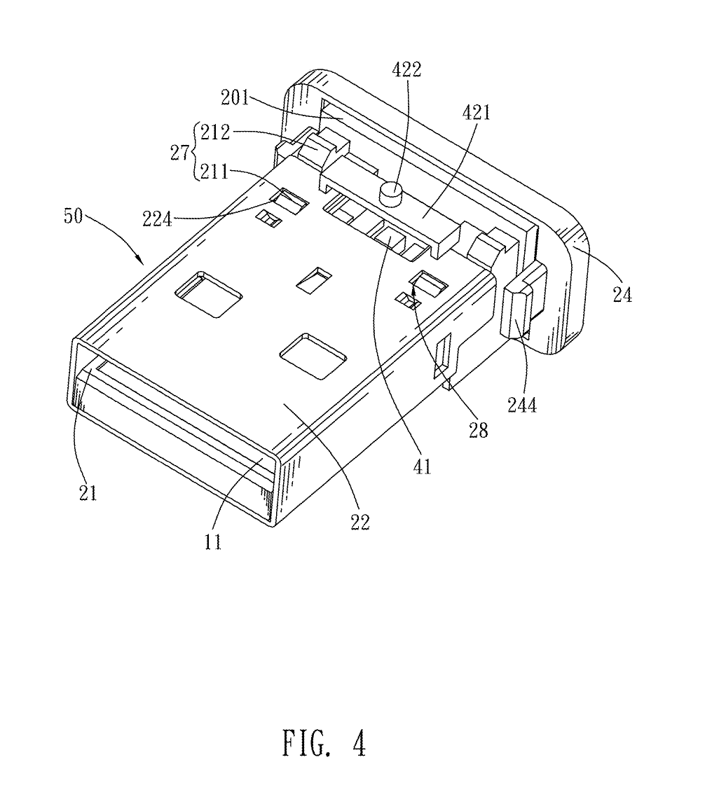

Referring to FIG. 1 to FIG. 4, the enclosure 20 includes a fixing holder 21, a shielding shell 22, a fastening holder 23, a front cover 24 and a protecting shell 25. The fixing holder 21, the shielding shell 22, the fastening holder 23 and the front cover 24 define a plurality of buckling portions 27, and a plurality of buckling holes 28 matched with the respective buckling portions 27. An insertion direction of the fingerprint flash drive 100 is defined as a front-to-rear direction. The enclosure 20 has a top surface 291 extending along the insertion direction of the fingerprint flash drive 100, and a front surface 292 connected with a front edge of the top surface 291. The front surface 292 and the top surface 291 of the enclosure 20 are noncoplanar. Preferably, the front surface 292 of the enclosure 20 is perpendicular to the top surface 291 of the enclosure 20. A middle of the top surface 291 of the enclosure 20 opens a through-hole 26.

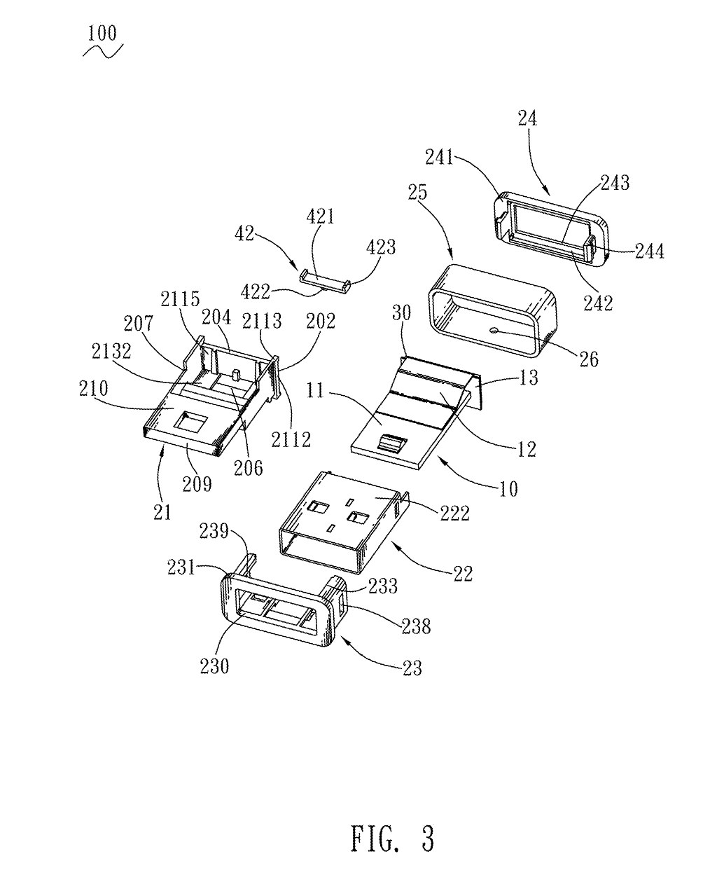

Referring to FIG. 2 and FIG. 3, the fixing holder 21 has a base board 201. The base board 201 has a top face 2111, two opposite side faces 2112 extended downward from two opposite sides of the top face 2111, a bottom face 2113 opposite to the top face 2111 and connected between bottoms of the two opposite side faces 2112, a front face 2114 connected among fronts of the top face 2111, the two side faces 2112 and the bottom face 2113, and a rear face 2115 connected among rears of the top face 2111, the two side faces 2112 and the bottom face 2113. Lower portions of two opposite sides of the rear face 2115 of the base board 201 extend rearward to form two lateral boards 203, respectively. An upper portion of the rear face 2115 of the base board 201 extends rearward to form an upper fixing board 205 connected between upper portions of front ends of the two lateral boards 203.

A middle of the front face 2114 of the base board 201 is recessed inward to form a limiting groove 202. A middle of the bottom face 2113 of the base board 201 is recessed inward to form a recess 204 communicated with the limiting groove 202. A front end of a middle of the upper fixing board 205 opens a first mouth 206. Rears of bottom surfaces of the two lateral boards 203 are recessed inward to form two first lacking grooves 207. Rears of top surfaces of the two lateral boards 203 are recessed downward to form two second lacking grooves 208 located above the two first lacking grooves 207, respectively. The fixing holder 21 further has a lower fixing board 210 connected between lower portions of rear ends of upper walls of the two first lacking grooves 207. A rear end of a top surface of the lower fixing board 210 protrudes upward to form a connecting board 209 connected between the rear ends of the upper walls of the two first lacking grooves 207.

So a receiving space 213 is surrounded among the base board 201, the two lateral boards 203, the upper fixing board 205, the lower fixing board 210 and the connecting board 209. The receiving space 213 includes a first receiving space 2131, and a second receiving space 2132 located behind and communicated with the first receiving space 2131. The first receiving space 2131 is formed among bottom walls of the two second lacking grooves 208, the connecting board 209 and the lower fixing board 210. The second receiving space 2132 is formed among the base board 201, the upper fixing board 205 and the front ends of the two lateral boards 203. Middles of two opposite sides of a top surface of the upper fixing board 205 protrude upward to form two first buckling portions 211, respectively.

Fronts of the two opposite sides of the top surface of the upper fixing board 205 protrude upward to form two second buckling portions 212 located in front of the two first buckling portions 211, respectively. The buckling portions 27 include the two first buckling portions 211 and the two second buckling portions 212. Outer sides of bottom surfaces of the two second buckling portions 212 are connected with top surfaces of the upper portions of the front ends of the two lateral boards 203, respectively. The first mouth 206 is located between the two second buckling portions 212. Rears of the two opposite sides of the top surface of the upper fixing board 205 are recessed inward to form two first restricting grooves 214 penetrating through two opposite sides of a rear surface of the upper fixing board 205, respectively. The two first restricting grooves 214 are located behind the two first buckling portions 211, respectively. A middle of a rear of the top surface of the upper fixing board 205 is recessed inward to form a second restricting groove 215 penetrating through a middle of the rear surface of the upper fixing board 205. The second restricting groove 215 is located between the two first restricting grooves 214.

Referring to FIG. 2 and FIG. 3 again, the shielding shell 22 is of a hollow rectangular shape. Middles of a front surface and a rear surface of the shielding shell 22 are opened freely. The shielding shell 22 is looped from a metal plate. The shielding shell 22 has an upper shielding plate 221, two side shielding plates 223 extended downward from two opposite sides of the upper shielding plate 221, and a lower shielding plate 222 facing the upper shielding plate 221 and connected with bottoms of the two side shielding plates 223. Two opposite sides of a front of the upper shielding plate 221 open two first buckling holes 224, respectively. A middle of a front edge of the upper shielding plate 221 is recessed inward to form a second mouth 225 located in front of an interval between the two first buckling holes 224. The two opposite sides of the front of the upper shielding plate 221 are punched inward to form two first restricting portions 226 located behind the two first buckling holes 224, respectively. A substantial middle of the upper shielding plate 221 is punched inward to form a second restricting portion 227.

The fastening holder 23 is of a hollow rectangular shape. The fastening holder 23 has a fastening frame 231 of a hollow rectangular shape. A middle of the fastening frame 231 opens an opening 230 penetrating through middles of a front surface and a rear surface of the fastening frame 231. An upper portion of the front surface of the fastening frame 231 extends frontward to form a top board 232. A lower portion of the front surface of the fastening frame 231 extends frontward to form a bottom board 233 facing the top board 232. Two opposite sides of the front surface of the fastening frame 231 extend frontward to form two side boards 234 respectively connected between the top board 232 and the bottom board 233. A middle of a front surface of the top board 232 is recessed inward to form an assembling groove 235 penetrating through middles of front ends of a top surface and a bottom surface of the top board 232.

Two opposite side walls of the assembling groove 235 vertically open two perforations 236, respectively. Two opposite sides of the top board 232 open two second buckling holes 237. The assembling groove 235 is located between the two second buckling holes 237. The two side boards 234 open two locking holes 238, respectively. A middle of a front surface of the bottom board 233 is recessed inward to form a gap 239 penetrating through a top surface and a bottom surface of the bottom board 233.

The front cover 24 has a main portion 241. A middle of a rear surface of the main portion 241 is recessed frontward to form a locating groove 242. A middle of a front surface of the main portion 241 of the front cover 24 is recessed rearward to form a receiving hole 243. The receiving hole 243 is communicated with a front of a middle of the locating groove 242. The receiving hole 243 is matched with the fingerprint recognizer 30. Two opposite sides of the rear surface of the main portion 241 extend rearward and then protrude outward to form two locking hooks 244. The locating groove 242 is located between the two locking hooks 244. The protecting shell 25 is of a rectangular frame shape. A middle of a top of the protecting shell 25 opens the through-hole 26.

The indicator light 40 includes a light source 41 and a light-permeating element 42. The light-permeating element 42 has a base portion 421. A middle of a top surface of the base portion 421 protrudes upward to form a protruding pillar 422. Two opposite sides of the base portion 421 protrude downward to form two insertion feet 423 spaced from each other.

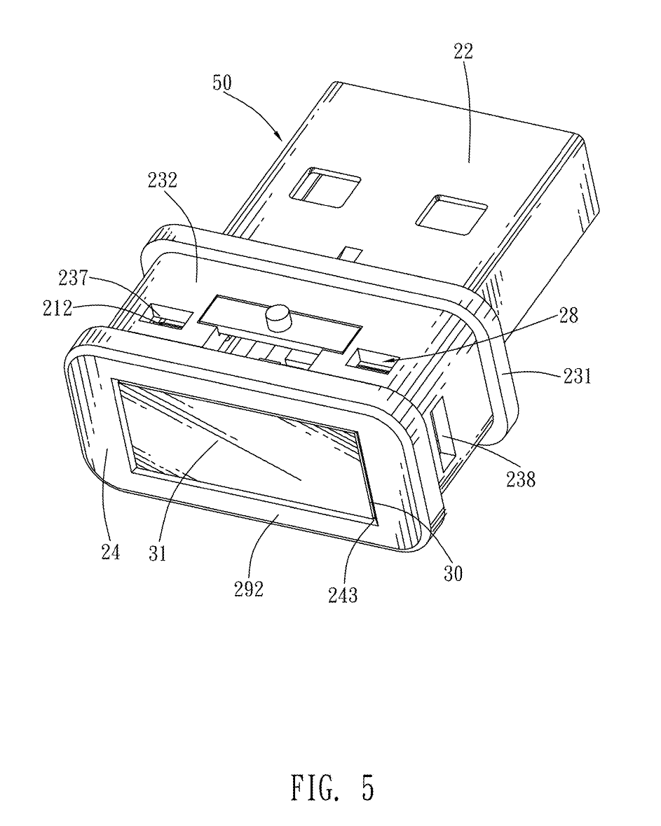

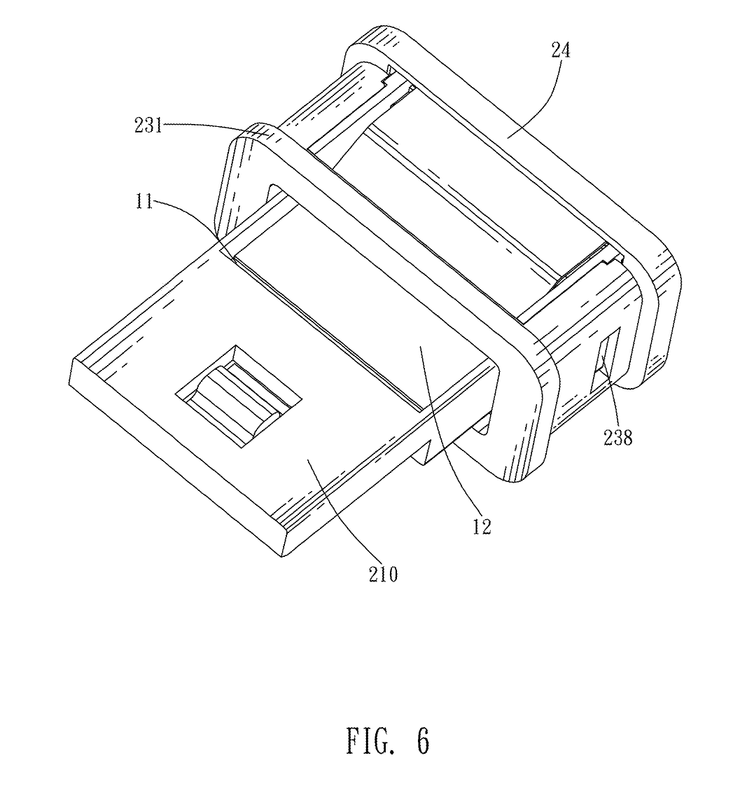

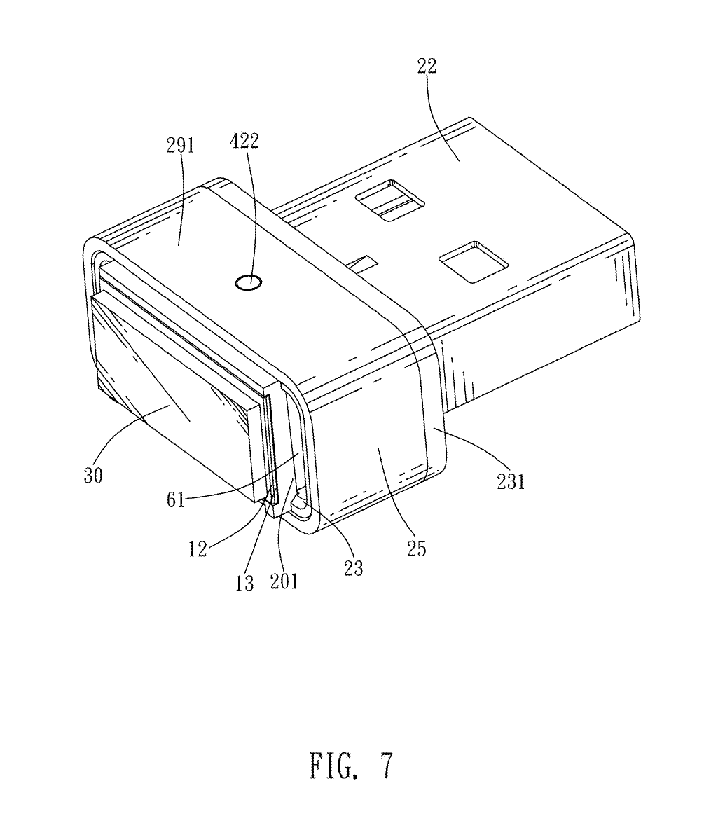

Referring to FIG. 1 to FIG. 7, when the fingerprint flash drive 100 is assembled, the enclosure 20 enclosing the circuit board 10. A rear end of the enclosure 20 cooperates with the circuit board 10 to form a plug 50. The fixing holder 21, the shielding shell 22, the fastening holder 23 and the front cover 24 are fastened together by virtue of the buckling portions 27 being buckled in the respective buckling holes 28.

The circuit board 10 is assembled in the fixing holder 21. The circuit board 10 is received in the receiving space 213. Specifically, the rigid circuit board 11 is received in the receiving space 213. A rear end of a top surface of the rigid circuit board 11 is exposed out of the fixing holder 21 from the first receiving space 2131. A front end of a bottom surface of the rigid circuit board 11 is exposed out of the fixing holder 21 from the second receiving space 2132. The reinforcing board 13 is limited in the limiting groove 202. The flexible circuit board 12 is received in the second receiving space 2132 of the receiving space 213. One end of the flexible circuit board 12 is mounted to and electrically connected with the front end of the bottom surface of the rigid circuit board 11, and the other end of the flexible circuit board 12 passes through recess 204 and is limited in the limiting groove 202. The one end of the flexible circuit board 12 is exposed outside from the second receiving space 2132. The other end of the flexible circuit board 12 is fastened to a front surface of the reinforcing board 13. The fingerprint recognizer 30 is mounted to a front surface of the flexible circuit board 12 and is electrically connected with the flexible circuit board 12 of the circuit board 10.

The shielding shell 22 surrounds an outside of a rear end of the fixing holder 21, and the shielding shell 22 is fastened to the outside of the rear end of the fixing holder 21 by virtue of the two first buckling portions 211 being buckled in the two first buckling holes 224. The shielding shell 22 cooperates with the rear end of the fixing holder 21 and the rigid circuit board 11 of the circuit board 10 to form the plug 50. Specifically, the upper shielding plate 221 is mounted on the rear of the top surface of the upper fixing board 205. The two first restricting portions 226 are restricted in the two first restricting grooves 214, respectively. The second restricting portion 227 is restricted in the second restricting groove 215. The lower shielding plate 222 is mounted to a bottom surface of the lower fixing board 210. Two opposite sides of a front edge of the lower shielding plate 222 abut against rear surfaces of front walls of the two first lacking grooves 207, respectively. The two side shielding plates 223 are attached to rear ends of outer surfaces of the two lateral boards 203, respectively.

The fastening holder 23 surrounds a front end of the fixing holder 21 and a front end of the shielding shell 22. Inner surfaces of two opposite sides of the fastening holder 23 face and are spaced from outer surfaces of two opposite sides of the fixing holder 21, so an insertion slot 61 is formed between the inner surface of each of the two opposite sides of the fastening holder 23 and the outer surface of one of the two opposite sides of the fixing holder 21. Specifically, the front ends of the fixing holder 21 and the shielding shell 22 are received in the opening 230. The fastening frame 231 is worn around the front end of the shielding shell 22. Inner surfaces of the two side boards 234 face and are spaced from the outer surfaces of the two lateral boards 203, respectively. The insertion slot 61 is formed between the inner surface of each of the two side boards 234 and the outer surface of one of the two lateral boards 203. Two opposite sides of a front surface of a rear wall of the gap 239 abut against the rear surfaces of the front walls of the two first lacking grooves 207, respectively. The assembling groove 235 is corresponding to the second mouth 225 and the first mouth 206. The two second buckling portions 212 are buckled in the two second buckling holes 237, respectively.

The front cover 24 is mounted to the front end of the fixing holder 21, and is fastened to the fastening holder 23. The main portion 241 is mounted to the front end of the fixing holder 21. The front end of the fixing holder 21 is received in the locating groove 242. Specifically, a front end of the base board 201 is received in the locating groove 242. The receiving hole 243 is corresponding to the limiting groove 202. Each of the two locking hooks 244 is inserted into the insertion slot 61. Free ends of the two locking hooks 244 hook in the two locking holes 238, respectively. The fingerprint recognizer 30 is electrically connected with the circuit board 10 and fastened to the front surface 292 of the enclosure 20. A front surface of the fingerprint recognizer 30 is exposed outside from the receiving hole 243. The front surface of the fingerprint recognizer 30 is defined as a touching surface 31. So the touching surface 31 of the fingerprint recognizer 30 is exposed outside from the receiving hole 243.

Preferably, the fingerprint recognizer 30 is vertically fastened to the front surface 292 of the enclosure 20 and perpendicular to the top surface 291 of the enclosure 20. The fingerprint recognizer 30 is received in the receiving hole 243. The touching surface 31 of the fingerprint recognizer 30 is perpendicular to the top surface 291 of the enclosure 20.

The indicator light 40 is mounted under the top surface 291 of the enclosure 20 and electrically connected to the circuit board 10. A top of the indicator light 40 is exposed to the top surface 291 of the enclosure 20 and received in the through-hole 26. The light source 41 is mounted to a front end of the top surface of the rigid circuit board 11 of the circuit board 10 and located under the first mouth 206, the second mouth 225 and the assembling groove 235. The base portion 421 is received in the assembling groove 235. The two insertion feet 423 are inserted into the two perforations 236, respectively. The protecting shell 25 surrounds a front end of the fastening holder 23. Specifically, the protecting shell 25 loops around outsides of the top board 232, the bottom board 233 and the two side boards 234. The protecting shell 25 is limited between a front end of the front cover 24 and a rear end of the fastening holder 23. The protecting shell 25 is limited between the fastening frame 231 and the main portion 241. The protruding pillar 422 is received in the through-hole 26. In use, the light source 41 provides signals for a user through the base portion 421 and the protruding pillar 422.

As described above, the fingerprint recognizer 30 is fastened to the front surface 292 of the enclosure 20 to properly utilize an area of the front surface 292 of the enclosure 20 and be without occupying an area of the top surface 291 of the enclosure 20 of the fingerprint flash drive 100, so a size of the fingerprint flash drive 100 is relatively smaller and is easy to decrease, and the front surface of the fingerprint recognizer 30 is exposed outside for being touched conveniently by the user. Moreover, the fixing holder 21, the shielding shell 22, the fastening holder 23 and the front cover 24 are fastened together by virtue of the buckling portions 27 being buckled in the respective buckling holes 28, and the process of fastening the fixing holder 21, the shielding shell 22, the fastening holder 23 and the front cover 24 is without using adhesives for preventing staining the fingerprint recognizer 30, in that case, quality of the fingerprint flash drive 100 is better, and the process of fastening the fixing holder 21, the shielding shell 22, the fastening holder 23 and the front cover 24 is convenient to decrease a cost and working hours of fastening the fixing holder 21, the shielding shell 22, the fastening holder 23 and the front cover 24 of the enclosure 20 of the fingerprint flash drive 100.

What is claimed is:

1. A fingerprint flash drive, comprising:
a circuit board;
an enclosure enclosing the circuit board, an insertion direction of the fingerprint flash drive being defined as a front-to-rear direction, the enclosure having a top surface extending along the insertion direction of the fingerprint flash drive, and a front surface connected with a front edge of the top surface, the front surface and the top surface of the enclosure being noncoplanar, a rear end of the enclosure cooperating with the circuit board to form a plug; and
a fingerprint recognizer electrically connected with the circuit board and fastened to the front surface of the enclosure, a front surface of the fingerprint recognizer being exposed outside.

2. The fingerprint flash drive as claimed in claim 1, wherein the front surface of the enclosure is perpendicular to the top surface of the enclosure, the fingerprint recognizer is vertically fastened to the front surface of the enclosure and perpendicular to the top surface of the enclosure.

3. The fingerprint flash drive as claimed in claim 1, wherein the enclosure includes a fixing holder, a shielding shell, a fastening holder and a front cover which define a plurality of buckling portions, and a plurality of buckling holes matched with the respective buckling portions, the fixing holder, the shielding shell, the fastening holder and the front cover are fastened together by virtue of the buckling portions being buckled in the respective buckling holes.

4. The fingerprint flash drive as claimed in claim 3, wherein the circuit board is assembled in the fixing holder, the shielding shell is of a hollow rectangular shape, middles of a front surface and a rear surface of the shielding shell are opened freely, the shielding shell surrounds and is fastened to an outside of a rear end of the fixing holder, the shielding shell cooperates with the rear end of the fixing holder and the circuit board to form the plug.

5. The fingerprint flash drive as claimed in claim 3, wherein the front cover is mounted to a front end of the fixing holder, and is fastened to the fastening holder.

6. The fingerprint flash drive as claimed in claim 3, wherein the front cover has a main portion, a middle of a front surface of the main portion is recessed rearward to form a receiving hole, the fingerprint recognizer is received in the receiving hole, the front surface of the fingerprint recognizer is exposed outside from the receiving hole.

7. The fingerprint flash drive as claimed in claim 6, wherein a middle of a rear surface of the main portion is recessed frontward to form a locating groove, the receiving hole is communicated with a front of a middle of the locating groove, the main portion is mounted to a front end of the fixing holder, the front end of the fixing holder is received in the locating groove.

8. The fingerprint flash drive as claimed in claim 7, wherein two opposite sides of the rear surface of the main portion extend rearward and then protrude outward to form two locking hooks, the locating groove is located between the two locking hooks, the fastening holder of a hollow rectangular shape surrounds the front end of the fixing holder and a front end of the shielding shell, inner surfaces of two opposite sides of the fastening holder face and are spaced from outer surfaces of two opposite sides of the fixing holder, so an insertion slot is formed between the inner surface of each of the two opposite sides of the fastening holder and the outer surface of one of the two opposite sides of the fixing holder, each of the two locking hooks is inserted into the insertion slot.

9. The fingerprint flash drive as claimed in claim 8, wherein the fastening holder has a fastening frame, a middle of the fastening frame opens an opening penetrating through middles of a front surface and a rear surface of the fastening frame, two opposite sides of the front surface of the fastening frame extend frontward to form two side boards, the front ends of the fixing holder and the shielding shell are received in the opening, the fixing holder has a base board, two opposite sides of a rear face of the base board extend rearward to form two lateral boards, respectively, inner surfaces of the two side boards face and are spaced from outer surfaces of the two lateral boards, respectively, the insertion slot is formed between the inner surface of each of the two side boards and the outer surface of one of the two lateral boards, each of the two locking hooks is inserted into the insertion slot.

10. The fingerprint flash drive as claimed in claim 9, wherein the two side boards open two locking holes, respectively, free ends of the two locking hooks hook in the two locking holes, respectively.

11. The fingerprint flash drive as claimed in claim 3, wherein the fixing holder has a base board, two opposite sides of a rear face of the base board extend rearward to form two lateral boards, respectively, an upper portion of the rear face of the base board extends rearward to form an upper fixing board connected between upper portions of front ends of the two lateral boards, rears of bottom surfaces of the two lateral boards are recessed inward to form two first lacking grooves, rears of top surfaces of the two lateral boards are recessed downward to form two second lacking grooves located above the two first lacking grooves, respectively, the fixing holder further has a lower fixing board connected between lower portions of rear ends of upper walls of the two first lacking grooves, a rear end of a top surface of the lower fixing board protrudes upward to form a connecting board connected between the rear ends of the upper walls of the two first lacking grooves, a receiving space is surrounded among the base board, the two lateral boards, the upper fixing board, the lower fixing board and the connecting board, the circuit board is received in the receiving space.

12. The fingerprint flash drive as claimed in claim 11, wherein the circuit board includes a rigid circuit board, a flexible circuit board and a reinforcing board, the rigid circuit board is received in the receiving space, a middle of a front face of the base board is recessed inward to form a limiting groove, a middle of a bottom face of the base board is recessed inward to form a recess communicated with the limiting groove, the reinforcing board is limited in the limiting groove, the flexible circuit board is received in the receiving space, one end of the flexible circuit board is mounted to and electrically connected with a front end of a bottom surface of the rigid circuit board, and the other end of the flexible circuit board passes through recess and is limited in the limiting groove, the other end of the flexible circuit board is fastened to a front surface of the reinforcing board.

13. The fingerprint flash drive as claimed in claim 12, wherein the fingerprint recognizer is mounted to a front surface of the flexible circuit board and is electrically connected with the flexible circuit board.

14. The fingerprint flash drive as claimed in claim 11, wherein the shielding shell has an upper shielding plate, two side shielding plates extended downward from two opposite sides of the upper shielding plate, and a lower shielding plate facing the upper shielding plate and connected with bottoms of the two side shielding plates, the upper shielding plate is mounted on a rear of a top surface of the upper fixing board, the lower shielding plate is mounted to a bottom surface of the lower fixing board, two opposite sides of a front edge of the lower shielding plate abut against rear surfaces of front walls of the two first lacking grooves, respectively, the two side shielding plates are attached to rear ends of outer surfaces of the two lateral boards, respectively.

15. The fingerprint flash drive as claimed in claim 14, wherein middles of two opposite sides of the top surface of the upper fixing board protrude upward to form two first buckling portions, respectively, two opposite sides of a front of the upper shielding plate open two first buckling holes, respectively, the shielding shell is fastened to an outside of a rear end of the fixing holder by virtue of the two first buckling portions being buckled in the two first buckling holes.

16. The fingerprint flash drive as claimed in claim 11, wherein the fastening holder has a fastening frame, an upper portion of a front surface of the fastening frame extends frontward to form a top board, fronts of two opposite sides of a top surface of the upper fixing board protrude upward to form two second buckling portions, respectively, two opposite sides of the top board open two second buckling holes, the two second buckling portions are buckled in the two second buckling holes, respectively.

17. The fingerprint flash drive as claimed in claim 1, further comprising an indicator light mounted under the top surface of the enclosure and electrically connected to the circuit board, a top of the indicator light being exposed to the top surface of the enclosure.

18. The fingerprint flash drive as claimed in claim 17, wherein a middle of the top surface of the enclosure opens a through-hole, the top of the indicator light is received in the through-hole.

19. The fingerprint flash drive as claimed in claim 3, further comprising an indicator light which includes a light source and a light-permeating element, the light-permeating element having a base portion, a middle of a top surface of the base portion protruding upward to form a protruding pillar, the enclosure further including a protecting shell surrounding a front end of the fastening holder, the protecting shell being limited between a front end of the front cover and a rear end of the fastening holder, a middle of a top of the protecting shell opening a through-hole, the light source being mounted to the circuit board, the protruding pillar being received in the through-hole.

20. The fingerprint flash drive as claimed in claim 19, wherein two opposite sides of the base portion protrude downward to form two insertion feet, the fastening holder has a fastening frame, an upper portion of a front surface of the fastening frame extends frontward to form a top board, a middle of a front surface of the top board is recessed inward to form an assembling groove penetrating through middles of front ends of a top surface and a bottom surface of the top board, two opposite side walls of the assembling groove vertically open two perforations, respectively, the base portion is received in the assembling groove, the two insertion feet are inserted into the two perforations, respectively.
